(19) United States
(12) Patent Application Publication
(10) Pub. No.: US 2002/0013016 A1
(43) Pub. Date: Jan. 31, 2002

(54) Method for fabricating semiconductor device

(76) Inventor: Seung Ho Lee, Chungcheongbuk-do (KR)

Correspondence Address: BIRCH STEWART KOLASCH & BIRCH, PO BOX 747, FALLS CHURCH, VA, 22040-0747, US

(21) Appl. No.: 09/873,320

(22) Filed: Jun. 5, 2001

(30) Foreign Application Priority Data
Jul. 19, 2000 (KR) 2000-41387

(51) Int. Cl. H01L 21/44; H01L 21/48; H01L 21/50

(52) U.S. Cl. 438/109; 257/768; 257/401; 257/408

(57) ABSTRACT

A semiconductor device with improved reliability is achieved by forming a gate electrode structure over a substrate, the gate electrode structure including a gate electrode over the substrate, an insulator on the gate electrode, and a sidewall spacer adjacent to the gate electrode and to the insulator thereon. The insulator is then removed to form a gap between the gate electrode and the sidewall spacer. Upon applying a salicide process to the gate electrode structure to form a salicide layer over the entire structure, the gap prevents bridging of salicide material formed on the gate electrode structure with the salicide material formed on the substrate.

### BACKGROUND OF THE INVENTION

1. Field of the Invention

The present invention relates to a method for fabricating a semiconductor device, and more particularly, to a method for fabricating a semiconductor device which improves reliability of the semiconductor device.

2. Background of the Related Art

Generally, with reduction of the size of a semiconductor device, the areas of the source/drain regions are reduced. In this case, it is necessary to thinly form a junction between the source and drain, causing a high resistance region to be formed.

To essentially reduce the resistance between the source/drain regions and a polysilicon region, a silicide process in which a metal silicide is formed at a junction area between the source/drain regions and the polysilicon region has been suggested. The silicide process, whereby the source/drain regions and a gate silicide region are formed at the same time, and a sidewall spacer is aligned with a gate terminal, is sometimes called a salicide process.

The related art method for fabricating a semiconductor device will be described with the accompanying drawings.

FIGS. 1a to 1g are sectional views showing fabricating process steps of the related art semiconductor device.

As shown in FIG. 1a, a device isolation region 12 having a shallow trench isolation (STI) structure is formed in a field region of a semiconductor substrate 11 in which the field region and an active region are defined. The device isolation region 12 is formed by forming a trench having a predetermined depth in the field region of the semiconductor substrate 11 and filling a gap-fill material inside the trench. Subsequently, n-type and p-type impurity ions are selectively injected into the active region of the semiconductor substrate 11 to form an N-well 13 and a P-well 14 in the semiconductor substrate 11.

As shown in FIG. 1b, a gate insulating film 15 is formed on the semiconductor substrate 11, and an undoped polysilicon layer 16 is formed on the gate insulating film 15. The n-type impurity ions are injected into the polysilicon layer 16 above the P-well 14 using a first photoresist (not shown) as a mask. The first photoresist is then removed, and the p-type impurity ions are injected into the polysilicon layer 16 above the N-well 13 using a second photoresist (not shown) as a mask. Afterwards, rapid thermal annealing (RTA) is performed in the polysilicon layer 16 on which the n-type and p-type impurity ions are doped, so as to improve doping efficiency of the impurity ions doped on the polysilicon layer 16.

As shown in FIG. 1c, the polysilicon layer 16 is selectively removed by photolithography and etching processes to selectively form a gate electrode 16a over a part of the semiconductor substrate 11 having the N-well 13 and the P-well 14 formed thereon.

Subsequently, lightly doped p-type and n-type impurity ions are selectively injected into the semiconductor substrate 11 using the gate electrode 16a as a mask to form lightly doped drain (LDD) regions 17 within the surface of the semiconductor substrate 11 at both sides of the gate electrode 16a. In other words, the lightly doped p-type impurity ions are injected into the N-well 13 while the lightly doped n-type impurity ions are injected into the P-well 14, so that the LDD regions 17 are formed.

As shown in FIG. 1d, an oxide film 18 and a nitride film 19 are sequentially formed on an entire surface of the semiconductor substrate 11 including the gate electrode 16a.

As shown in FIG. 1e, the nitride film 19 and the oxide film 18 are etched back to form a sidewall spacer 20 including the oxide film 18 and the nitride film 19 at both sides of the gate electrode 16a. Meanwhile, an edge portion of the device isolation region 12 is removed by the etch-back process when forming the sidewall spacer 20.

As shown in FIG. 1f, the surface of the semiconductor substrate 11 is cleaned and then a selective epitaxial growth (SEG) process is performed on the surfaces of the exposed semiconductor substrate 11 and the gate electrode 16a to selectively form an epitaxial layer 21 having a thickness of 300˜500Å. Subsequently, heavily doped p-type and n-type impurity ions for the source and drain are injected into the semiconductor substrate 11 to form source/drain impurity regions 22, which are connected with the LDD region 17, within the surface of the semiconductor substrate 11.

As shown in FIG. 1g, the epitaxial layer 21 is reacted with the semiconductor substrate 11 and the gate electrode 16a by the salicide process to form a salicide layer 23.

Reference numeral 24 denotes a portion where the volume of the epitaxial layer 21 has expanded during the above described salicide process.

When a deep submicron Complementary Metal-Oxide-Semiconductor (CMOS) device is fabricated, the length of the gate becomes short. Accordingly, in order to improve process margin, it is necessary to lower the height of the gate stack. If the height of the gate stack is high, a shadow effect occurs during ion implantation due to an adjacent gate, thereby deteriorating the characteristics of the device.

However, the aforementioned related art method for fabricating a semiconductor device has several problems. First, the distance between the gate electrode and the epitaxial layer 21 grown in a diffusion region becomes too close due to the SEG process being performed on a gate stack having a limited height, thus increasing the probability of bridging therebetween. Furthermore, the volume of the epitaxial layer 21 undesirably expands during the salicide process, thus causing electrical shorts between the gate electrode and the source/drain regions, which is especially problematic when line widths need to be narrow.

### SUMMARY OF THE INVENTION

The present invention solves at least the above problems and/or disadvantages and provides at least the advantages described hereinafter.

Also, the present invention provides a method for fabricating a semiconductor device that substantially obviates one or more of the problems due to limitations and disadvantages of the related art.

Furthermore, the present invention provides a method for fabricating a semiconductor device in which an SEG process is performed effectively and safely to prevent electrical shorting and bridging from occurring between the gate electrode and the source/drain regions.

Additional advantages and features of the invention will be set forth in part in the description which follows and in part will become apparent to those having ordinary skill in the art upon examination of the following disclosure or may be learned from practice of the invention. The advantages of the invention may be realized and attained as particularly pointed out in the appended claims.

To achieve at least these and other advantages in whole or in part, and in accordance with purposes of the present invention, as embodied and broadly described, a method for fabricating a semiconductor device according to the present invention includes the steps of: forming a gate insulating film on a semiconductor substrate; sequentially forming a gate electrode and a gate cap insulating film on some region of the gate insulating film; forming a lightly doped impurity region inside a surface of the semiconductor substrate at both sides of the gate electrode; sequentially forming a first insulating film and a second insulating film on an entire surface of the semiconductor substrate including the gate cap insulating film and the gate electrode; selectively removing the second insulating film and the first insulating film to form a sidewall spacer at both sides of the gate cap insulating film and the gate electrode; removing the gate cap insulating film to expose a surface of the gate electrode; forming a semiconductor layer on the surfaces of the exposed gate electrode and the semiconductor substrate; forming a heavily doped impurity region, which is connected with the lightly doped impurity region, inside the surface of the semiconductor substrate at both sides of the gate electrode; and reacting the semiconductor substrate with the semiconductor layer and the gate electrode by salicide process to form a salicide layer.

It is to be understood that both the foregoing general description and the following detailed description are exemplary and explanatory and are intended to provide further explanation of the invention as claimed.

### BRIEF DESCRIPTION OF THE DRAWINGS

The invention will be described in detail with reference to the following drawings in which like reference numerals refer to like elements wherein:

Figs. 1a to 1g are sectional views showing fabricating process steps of a related art semiconductor device; and

FIGS. 2a to 2g are sectional views showing fabricating process steps of a semiconductor device according to the present invention.

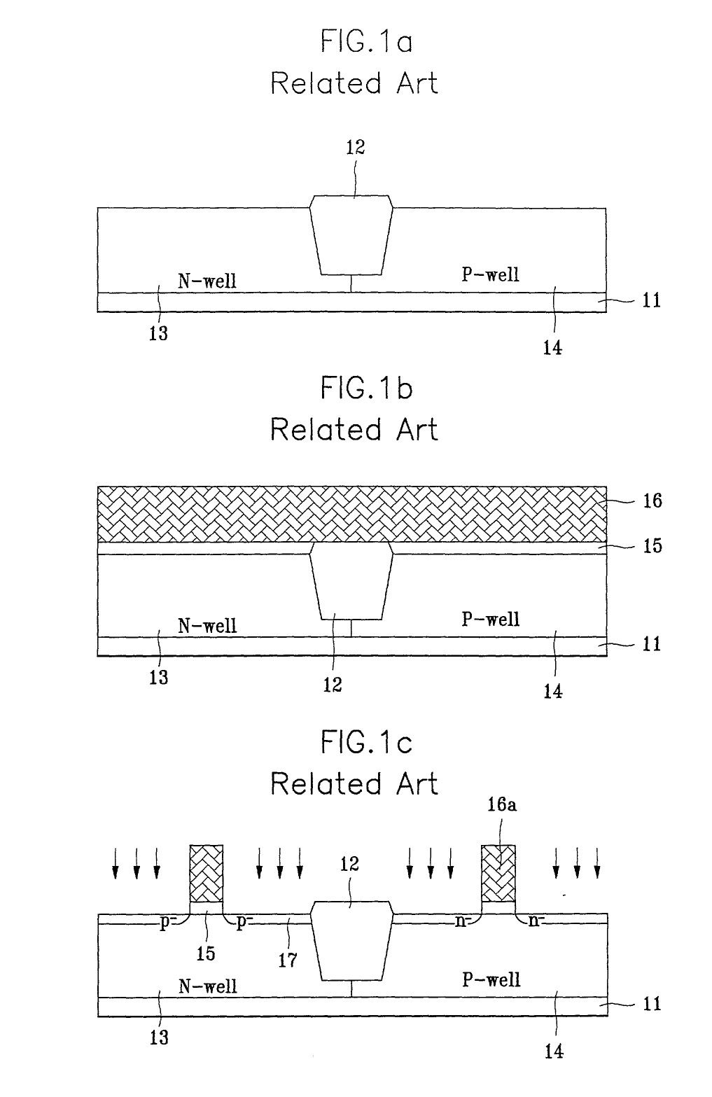

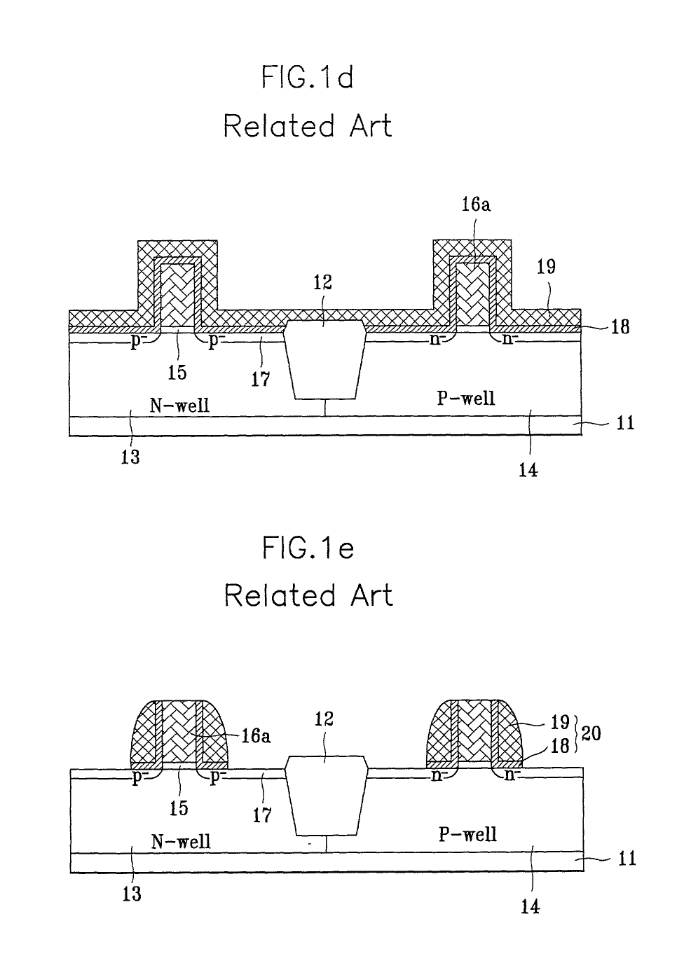

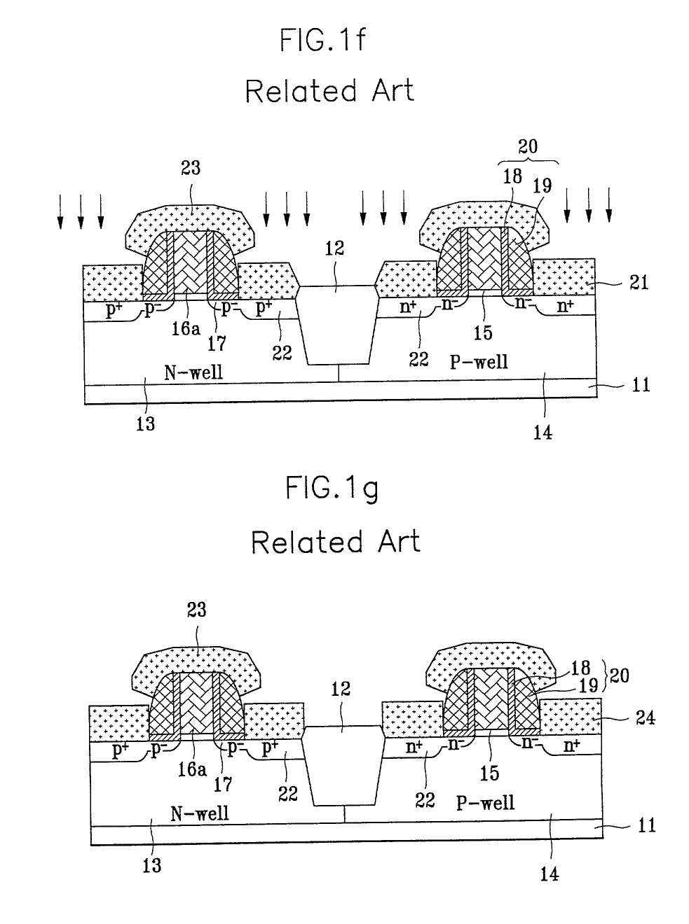

### DETAILED DESCRIPTION OF PREFERRED EMBODIMENTS

Reference will now be made in detail to the preferred embodiments of the present invention, examples of which are illustrated in the accompanying drawings.

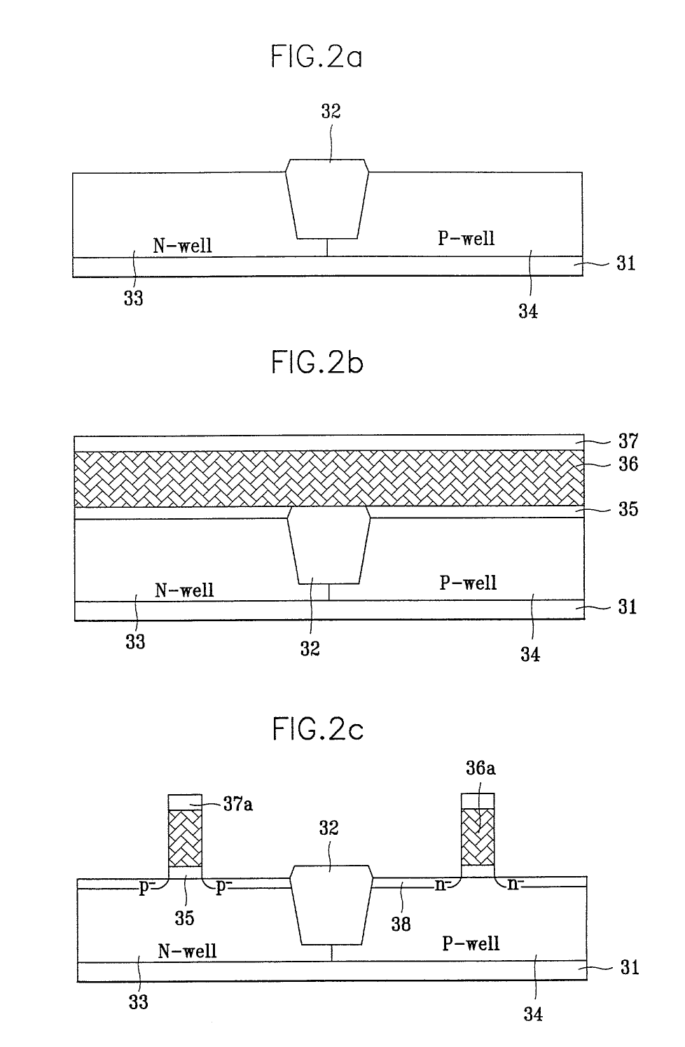

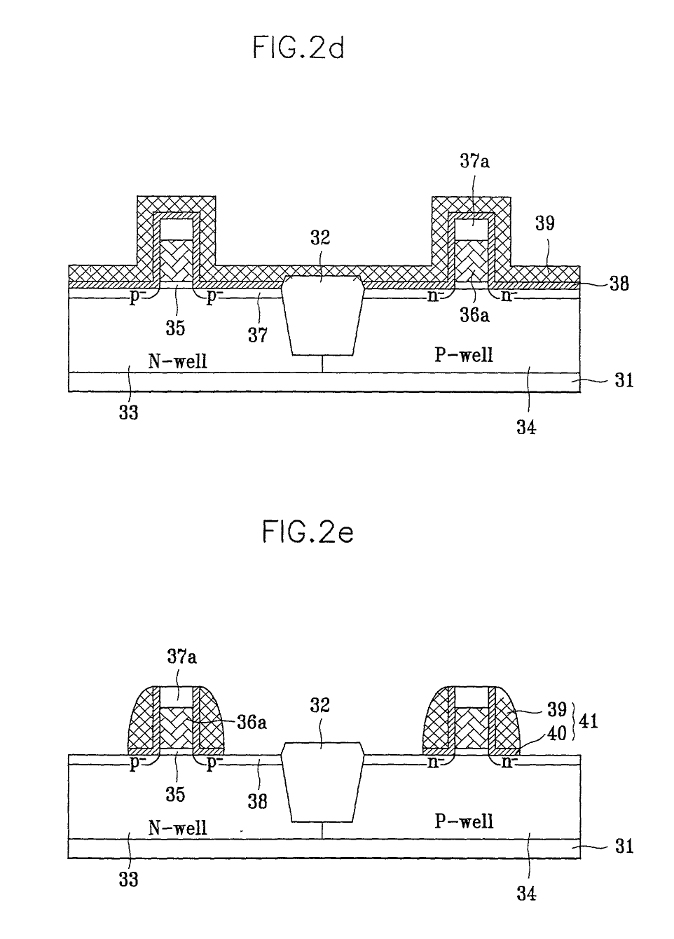

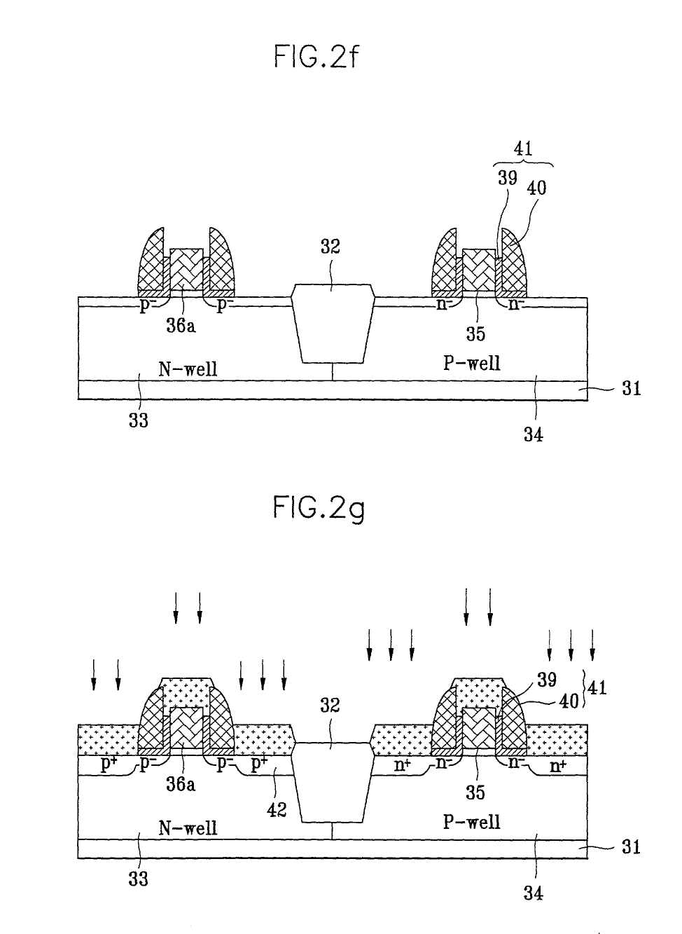

As shown in FIG. 2a, a device isolation region 32 having a shallow trench isolation (STI) structure is formed in a field region of a semiconductor substrate 31 in which the field region and an active region are defined. The device isolation region 32 is formed by forming a trench having a predetermined depth in the field region of the semiconductor substrate 31 and filling a gap-fill material inside the trench. Subsequently, n-type and p-type impurity ions are selectively injected into the active region of the semiconductor substrate 31 to form an N-well 33 and a P-well 34 inside a surface of the semiconductor substrate 31.

As shown in FIG. 2b, a gate insulating film 35 is formed on the semiconductor substrate 31, and an undoped polysilicon layer 36 and a first insulating film 37 are sequentially formed on the gate insulating film 35. The gate insulating film 35 is formed by oxidizing the semiconductor substrate 31 or being deposited on the semiconductor substrate 31 by chemical vapor deposition (DVD) process. The n-type impurity ions are injected into the polysilicon layer 36 on the P-well 34 using a first photoresist (not shown) as a mask. The first photoresist is then removed, and the p-type impurity ions are injected into the polysilicon layer 36 on the N-well 33 using a second photoresist (not shown) as a mask. Afterwards, rapid thermal annealing (RTA) is performed in the polysilicon layer 36 on which the n-type and p-type impurity ions are doped, so as to improve doping efficiency of the impurity ions doped on the polysilicon layer 36. The first insulating film 37 is formed by depositing an oxide film having a thickness of 300˜500Å. A material having a dry-etching ratio three times higher than that of the device isolation region 32 is used as the first insulating film 37.

As shown in FIG. 2c, the first insulating film 37, the polysilicon layer 36 and the gate insulating film 35 are selectively removed by photolithography and etching processes to form a gate cap insulating film 37a and a gate electrode 36a in some region of the semiconductor substrate 31 in which the N-well 33 and the P-well 34 are formed.

Subsequently, lightly doped p-type and n-type impurity ions are selectively injected into the semiconductor substrate 31 using the gate cap insulating film 37a and the gate electrode 36a as masks to form LDD regions 38 inside the surface of the semiconductor substrate 31 at both sides of the gate electrode 36a. In other words, the lightly doped p-type impurity ions are injected into the N-well 33 while the lightly doped n-type impurity ions are injected into the P-well 34, so that the LDD regions 38 are formed.

As shown in FIG. 2d, a second insulating film 39 and a third insulating film 40 are sequentially formed on an entire surface of the semiconductor substrate 31 including the gate cap insulating film 37a.

The second insulating film 39 can be formed of an oxide film while the third insulating film 40 can be formed of a nitride film. That is to say, the second insulating film 39 and the third insulating film 40 are formed of materials having different etching ratios.

As shown in FIG. 2e, the third insulating film 40 and the second insulating film 39 are etched back to form a sidewall spacer 41 including the second insulating film 39 and the third insulating film 40 at both sides of the gate cap insulating film 37a and the gate electrode 36a.

As shown in FIG. 2f, the gate cap insulating film 37a is removed by wet-etching process. At this time, the second insulating film 39 constituting the sidewall spacer 41 is formed of the same oxide film as the gate cap insulating film 37a. Accordingly, an upper surface and both sides of the second insulating film 39 are selectively removed to form an under cut shape.

Meanwhile, the surface of the semiconductor substrate 31 is cleaned by a washing process and at the same time the gate cap insulating film 37a is removed.

As shown in FIG. 2g, the SEG process is performed on the surfaces of the exposed semiconductor substrate 31 and the gate electrode 36a to form an epitaxial layer having a thickness of 300˜500Å.

Subsequently, heavily doped p-type and n-type impurity ions for a source and a drain are injected into the semiconductor substrate 31 to form source/drain impurity regions 42, which are connected with the LDD regions 38, inside the surface of the semiconductor substrate 31. In other words, the heavily doped p-type impurity ions are injected into the N-well 33 while the heavily doped n-type impurity ions are injected into the P-well 34, so that the source/drain impurity regions 42 are formed.

Thereafter, the epitaxial layer is reacted with the semiconductor substrate 31 and the gate electrode 36a by the salicide process to form a salicide layer 43.

In summary, according to the present invention, after the gate cap insulating film 37a is formed on the gate electrode 36a, the sidewall spacer 41 including the second insulating film 39 and the third insulating film 40 is formed. The gate cap insulating film 37a is removed by wet-etching process using the third insulating film 40 of the sidewall spacer 41 as a mask and at the same time the surface of the semiconductor substrate is cleaned by washing process. Finally, the SEG process and the salicide process are sequentially performed on the semiconductor substrate 31 to form an electrode metal of low resistance.

The aforementioned method for fabricating a semiconductor device according to the present invention has the following advantages.

First, since the under cut shape is formed by selectively removing the upper surface and both sides of the second insulating film, bridging that may be caused during the SEG process is prevented from occurring between the gate and the diffusion region. That is, bridging between the diffusion region and the epitaxial layer grown on the diffusion region due to overflow of the epitaxial layer grown on the gate is prevented from occurring. Furthermore, it is possible to prevent electrical shorts between the gate and the source/drain regions due to expansion of the epitaxial layer during the salicide process.

The foregoing embodiments and advantages are merely exemplary and are not to be construed as limiting the present invention. The present teachings can be readily applied to other types of apparatuses. The description of the present invention is intended to be illustrative, and not to limit the scope of the claims. Many alternatives, modifications, and variations will be apparent to those skilled in the art.

What is claimed is:

1. A method of fabricating a semiconductor device comprising:
forming a gate insulating film on a semiconductor substrate;
sequentially forming a gate electrode and a gate cap insulating film on a predetermined region of the gate insulating film;
forming a lightly doped impurity region inside a surface of the semiconductor substrate at both sides of the gate electrode;
sequentially forming a first insulating film and a second insulating film on an entire surface of the semiconductor substrate including the gate cap insulating film and the gate electrode;
selectively removing the second insulating film and the first insulating film to form a sidewall spacer at both sides of the gate cap insulating film and the gate electrode;
removing the gate cap insulating film to expose a surface of the gate electrode;
forming a semiconductor layer on surfaces of the exposed gate electrode and the semiconductor substrate;
forming a heavily doped impurity region, which is connected with the lightly doped impurity region, inside a surface of the semiconductor substrate at both sides of the gate electrode; and
reacting the semiconductor substrate with the semiconductor layer and the gate electrode by salicide process to form a salicide layer.

2. The method of claim 1, wherein the first insulating film and the second insulating film are formed of materials having different etching ratios.

3. The method of claim 1, wherein the gate cap insulating film and the first insulating film are formed of materials having the same etching ratio.

4. The method of claim 1, wherein the gate cap insulating film is formed of an oxide film.

5. The method of claim 1, wherein the first insulating film is formed of an oxide film.

6. The method of claim 1, wherein the second insulating film is formed of a nitride film.

7. The method of claim 1, wherein the semiconductor layer is formed by a selective epitaxial growth (SEG) process.

8. The method of claim 1, wherein the gate cap insulating film is removed by wet-etching process.

9. The method of claim 1, wherein the gate cap insulating film has a thickness of 300˜500Å.

10. The method of claim 1, wherein the semiconductor layer has a thickness of 300˜500Å.

11. A method of fabricating a semiconductor device comprising:
forming a first conductive type well and a second conductive type well in a semiconductor substrate;
sequentially forming a gate insulating film, an undoped conductive layer, and a first insulating film on an entire surface of the semiconductor substrate;
selectively doping impurity ions on the undoped conductive layer and performing annealing thereto;
selectively removing the first insulating film and the conductive layer to form a gate cap insulating film and a gate electrode;
respectively forming lightly doped impurity regions of a second conductive type and a first conductive type in the first conductive type well and the second conductive type well at both sides of the gate electrode;
sequentially forming a second insulating film and a third insulating film on the entire surface of the semiconductor substrate including the gate electrode;
selectively removing the third insulating film and the second insulating film to form a sidewall spacer at both sides of the gate cap insulating film and the gate electrode;
selectively removing the gate cap insulating film to expose a surface of the gate electrode;
forming a semiconductor layer on surfaces of the exposed gate electrode and the semiconductor substrate;
forming heavily doped impurity regions of a second conductive type and a first conductive type, which are connected with the lightly doped impurity regions, inside a surface of the semiconductor substrate at both sides of the gate electrode; and
reacting the semiconductor substrate with the semiconductor layer and the gate electrode by salicide process to form a salicide layer.

12. The method of claim 11, wherein the second insulating film and the third insulating film are formed of materials having different etching ratios.

13. The method of claim 11, wherein the gate cap insulating film and the second insulating film are formed of materials having a same etching ratio.

14. The method of claim 11, wherein the gate cap insulating film is formed of an oxide film.

15. The method of claim 11, wherein the second insulating film is formed of an oxide film.

16. The method of claim 11, wherein the third insulating film is formed of a nitride film.

17. The method of claim 11, wherein the semiconductor layer is formed by a selective epitaxial growth (SEG) process.

18. The method of claim 11, wherein the gate cap insulating film is removed by wet-etching process.

19. The method of claim 11, wherein the gate cap insulating film has a thickness of 300˜500Å.

20. The method of claim 11, wherein the semiconductor layer has a thickness of 300˜500Å.

21. The method of claim 11, wherein the annealing is performed by rapid thermal annealing (RTA).

22. A method of forming a semiconductor device comprising:
forming a gate electrode structure over a substrate, the gate electrode structure including a gate electrode, an insulator on the gate electrode, and a sidewall spacer adjacent to the gate electrode and to the insulator thereon;
removing the insulator; and
forming a salicide layer over the gate electrode structure after the insulator is removed.

23. The method of claim 22, wherein forming the salicide layer comprises:
forming an epitaxial layer on the substrate and on the gate electrode; and processing the epitaxial layer into a salicide layer.

24. The method of claim 22, wherein the step of removing the insulator is performed by etching the insulator so that a height of the sidewall spacer is greater than a height of the gate electrode.

25. The method of claim 22, wherein the step of removing the insulator is performed by etching a portion of the sidewall spacer so that a groove is formed between the gate electrode and the sidewall spacer.

26. A semiconductor device comprising:
a gate electrode structure over a substrate, the gate electrode structure including a gate electrode, and at least two sidewall spacers adjacent to at least two sides of the gate electrode, a height of the sidewall spacers being greater than a height of the gate electrode resulting in a gap defined between the sidewall spacers and above the gate electrode; and
a salicide material on the gate electrode structure and on the substrate, wherein a portion of the salicide material on the gate electrode structure is in the gap.

27. The device of claim 26, wherein the sidewall spacers and the gate electrode further define a groove therebetween.

28. The device of claim 27, wherein a portion of the salicide material on the gate electrode structure is in the groove.

29. The device of claim 26, wherein the sidewall spacer comprises a first layer contacting the sides of the gate electrode, and a second layer over the first layer.

30. The device of claim 29, wherein the first layer is of oxide material.

31. The device of claim 30, wherein the second layer is of nitride material.
